(19) United States
(12) Patent Application Publication
(10) Pub. No.: US 2022/0085142 A1
(43) Pub. Date: Mar. 17, 2022

(54) MODULAR COUPLED MAGNETIC VOLTAGE REGULATORS

(71) Applicant: Intel Corporation, Santa Clara, CA (US)

(72) Inventor: Beomseok CHOI, Chandler, AZ (US)

(21) Appl. No.: 17/020,467

(22) Filed: Sep. 14, 2020

(51) Int. Cl. H01L 49/02; G05F 1/10; H01F 17/04; H01L 23/498; H01L 23/64; H01F 17/00

(52) U.S. Cl. CPC H01L 28/10; G05F 1/10; H01F 17/04; H01F 2017/002; H01L 23/645; H01F 17/0013; H01F 2017/0066; H01L 23/49827

(57) ABSTRACT

Embodiments disclosed herein include modular transformers that comprise a plurality of interconnected transformer modules. In an embodiment a transformer module comprises a first core, where the first core is conductive, and a second core adjacent to the first core, where the second core is conductive. In an embodiment, the transformer module further comprises a magnetic layer around the first core and the second core. In an embodiment, a first via through the magnetic layer is connected to the first core, and a second via through the magnetic layer is connected to the first core. In an embodiment, a third via through the magnetic layer is connected to the second core, and a fourth via through the magnetic layer is connected to the second core.

### TECHNICAL FIELD

Embodiments of the present disclosure relate to semiconductor devices, and more particularly to electronic packages with modular transformers for voltage regulators (VRs).

### BACKGROUND

Switched mode voltage regulators are popular for their high efficiency. Many voltage regulator (VR) topologies with coupled magnetics and transformers achieve very high efficiency, especially for high voltage conversion ratios, and power densities using soft-switching and high magnetic component utilization. However, they require bulky magnetics, which limit their application for fully integrated voltage regulators (FIVRs) or on-package voltage regulators (OPVRs). Due to this design constraint, most small form factor VRs (e.g., FIVR and OPVR) use very simple topologies that use minimal amounts of magnetic material. This limits the achievable efficiency.

Most small VR solutions are designed with tradeoffs for either efficiency or form factor in order to meet other component requirements. Coupled magnetic structures require high permeability magnetic material and careful design to achieve the high coupling. Such designs have traditionally had large transformer like structures to enable the high coupling. Furthermore, routing of such topologies is difficult, and results in a decrease in performance. For computing applications, most high voltage conversion ratio VRs targeting high efficiency use transformers to achieve the needed voltage conversion (e.g., from 48V to 1V), but are placed on the platform and consume a lot of valuable real estate.

### BRIEF DESCRIPTION OF THE DRAWINGS

FIG. 1A is a perspective view illustration of a transformer module with a pair of conductive cores embedded in a magnetic layer, in accordance with an embodiment.

FIG. 1B is an electrical equivalent of the transformer module in FIG. 1A, in accordance with an embodiment.

FIG. 2A is a perspective view illustration of a transformer module with first taps and second taps on opposite ends of the transformer module, in accordance with an embodiment.

FIG. 2B is a perspective view illustration of a transformer module with first taps, second taps, and third taps, in accordance with an embodiment.

FIG. 2C is a perspective view illustration of a modular transformer comprising a pair of transformer modules arranged end-to-end, in accordance with an embodiment.

FIG. 3A is an electrical schematic of a modular transformer with a pair of unconnected transformer modules, in accordance with an embodiment.

FIG. 3B is an electrical schematic of the modular transformer with transformer modules that are connected to provide a 2:1 transformer, in accordance with an embodiment.

FIG. 3C is an electrical equivalent circuit of the modular transformer of FIG. 3B, in accordance with an embodiment.

FIG. 4 is a schematic of a voltage regulator VR system that includes a modular transformer with a 2:1 ratio, in accordance with an embodiment.

FIG. 5A is an electrical schematic of a modular transformer with transformer modules that are connected to provide a 4:1 transformer, in accordance with an embodiment.

FIG. 5B is an electrical equivalent circuit of the modular transformer of FIG. 5A, in accordance with an embodiment.

FIGS. 6A and 6B are cross-sectional illustrations of a modular transformer embedded in a package substrate, in accordance with various embodiments.

FIGS. 7A-7D are illustrations of an electronic system with a modular transformer attached over an interposer, in accordance with various embodiments.

FIGS. 8A-8D are cross-sectional illustrations of an electronic system with a modular transformer attached below an interposer, in accordance with various embodiments.

FIGS. 9A and 9B are cross-sectional illustrations of an electronic system with a modular transformer passing through an interposer, in accordance with various embodiments.

FIGS. 10A-10C are cross-sectional illustrations of an electronic system with a modular transformer embedded in a package substrate, in accordance with various embodiments.

FIG. 11 is a schematic of a computing device built in accordance with an embodiment.

### EMBODIMENTS OF THE PRESENT DISCLOSURE

Described herein are electronic packages with modular transformers for voltage regulators (VRs), in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, high efficiency voltage regulator (VR) topologies are difficult to integrate into the electronic package, especially for small form factor VRs (e.g., fully integrated voltage regulators (FIVR) and on-package voltage regulators (OPVR)). This is due, at least in part, to the large volume of magnetic material needed to provide the coupling between inductors of a transformer.

Accordingly, embodiments disclosed herein include transformer modules with highly coupled inductors. Each transformer module utilizes a pair of conductive cores that are surrounded by a magnetic layer. Since both conductive cores are embedded within the same magnetic layer, there is a high degree of coupling. Additionally, a plurality of transformer modules may be electrically coupled together to provide a modular solution enabling any desired transformer ratio. For example, the primary windings of each transformer module may be connected in series, while the secondary windings of each transformer module may be electrically isolated from each other. That is, each of the secondary windings may provide voltage to different domains.

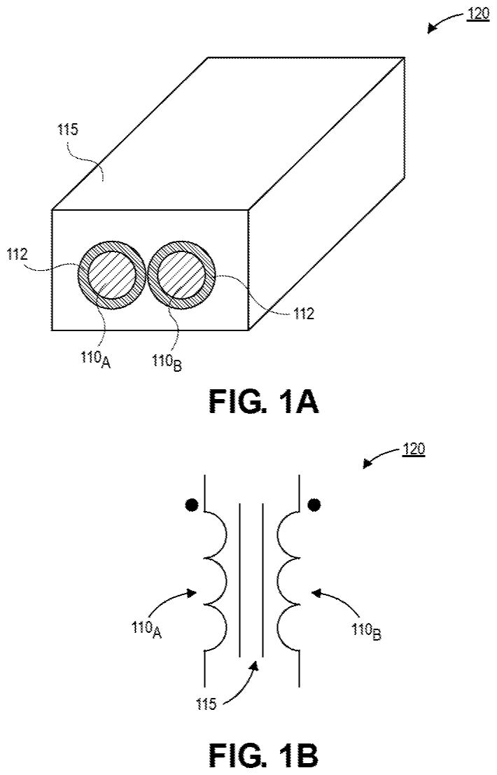

Referring now to FIG. 1A, a perspective view illustration of a transformer module 120 is shown, in accordance with an embodiment. In an embodiment, the transformer module 120 may comprise a first conductive core 110_{A} and a second conductive core 110_{B}. For example, the first conductive core 110_{A} and the second conductive core 110_{B} may comprise copper or another conductive material. The first conductive core 110_{A} and the second conductive core 110_{B} may each be surrounded by an insulating layer 112. The insulating layers 112 allow for the first conductive core 110_{A} and the second conductive core 110_{B} to be brought close to each other without shorting. For example, the insulating layer 112 of the first conductive core 110_{A} may be in direct contact with the insulating layer 112 of the second conductive core 110_{B}.

In an embodiment, a magnetic layer 115 surrounds the first conductive core 110_{A} and the second conductive core 110_{B}. That is, the first conductive core 110_{A} and the second conductive core 110_{B} may be referred to as being embedded in the magnetic layer 115. Providing the first conductive core 110_{A} and the second conductive core 110_{B} within the same magnetic layer 115 allows for a high degree of coupling between the two conductive cores 110_{A} and 110_{B}.

The magnetic layer 115 may be a molded magnetic material in some embodiments. In other embodiments, the magnetic layer 115 may be a sheet that is wrapped around the first conductive core 110_{A} and the second conductive core 110_{B}. In an embodiment, the magnetic layer 115 may comprise any suitable magnetic material. For example, the magnetic layer 115 may comprise, but is not limited to, ferrites, iron, aluminum, cobalt, and nickel. In the case of a molded magnetic layer 115, the magnetic layer 115 may comprise an epoxy that is filled with magnetic filler particles. In some embodiments, the magnetic layer 115 may be a high magnetic permeability material. For example, the magnetic permeability of the magnetic layer 115 may be approximately 10μ/μ₀ or greater.

Referring now to FIG. 1B, an electrical schematic representation of the transformer module 120 is shown, in accordance with an embodiment. As shown, the transformer module 120 electrically functions as a transformer with the first conductive core 110_{A} being a first inductor and the second conductive core 110_{B} being the second inductor. The two inductors are coupled together by the magnetic layer 115.

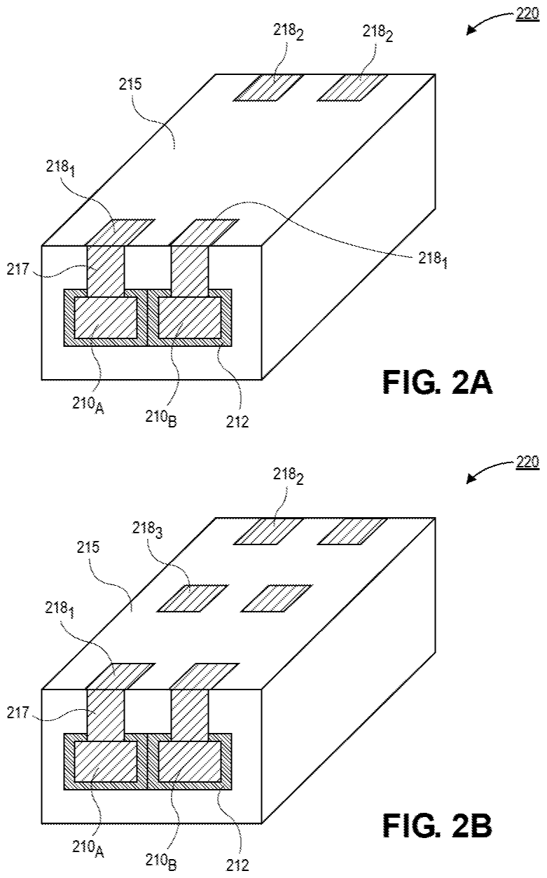

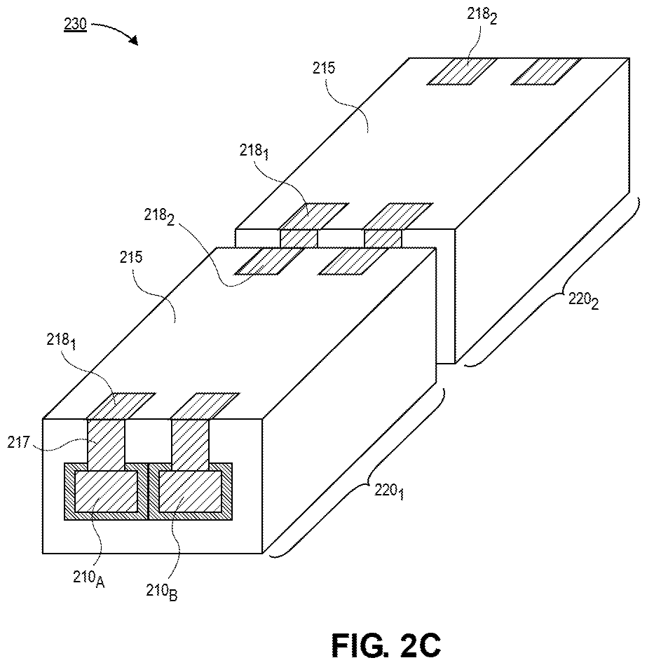

Referring now to FIG. 2A, a perspective view illustration of a transformer module 220 is shown, in accordance with an embodiment. The transformer module 220 illustrates the architecture used to make electrical connections to the first conductive core 210_{A} and the second conductive core 210_{B}. As shown, conductive vias 217 may pass through the insulating layer 212 and the magnetic layer 215. The vias 217 may electrically couple the conductive cores 210_{A} and 210_{B} to pads 218 on an outer surface of the magnetic layer 215. In an embodiment, each conductive core 210 may include a first pad 218₁ and a second pad 218₂. The first pad 218₁ may be provided proximate to a first end of the transformer module 220, and the second pad 218₂ may be provided proximate to a second end of the transformer module 220.

Referring now to FIG. 2B, a perspective view illustration of a transformer module 220 is shown, in accordance with an additional embodiment. The transformer module 220 in FIG. 2B may be substantially similar to the transformer module 220 in FIG. 2A, with the exception of the inclusion of third pads 218₃. The third pads 218₃ may be provided between the first pads 218₁ and the second pads 218₂. For example, the third pads 218₃ may be substantially equidistant to the first pads 218₁ and the second pads 218₂. The third pads 218₃ provide a tap along the length of the conductive cores 210_{A} and 210_{B}.

Referring now to FIG. 2C, a perspective view illustration of a modular transformer 230 is shown, in accordance with an embodiment. In an embodiment, the modular transformer 230 comprises a first transformer module 220₁ and a second transformer module 220₂. The first transformer module 220₁ and the second transformer module 220₂ may be arranged end-to-end with each other. The first transformer module 220₁ and the second transformer module 220B may be substantially similar to the transformer modules 220 described above with respect to FIGS. 2A and 2B.

In the illustrated embodiments, the pads 218 of the modular transformer 230 are shown unconnected. However, it is to be appreciated that connections between pads 218 may be provided in order to electrically couple the first transformer module 220₁ to the second transformer module 220₂, as will be described in greater detail below. For example, the second pad 218₂ of the first conductive core 210_{A} in the first transformer module 220₁ may be electrically connected to the first pad 218₁ of the first conductive core 210_{A} in the second transformer module 220₂.

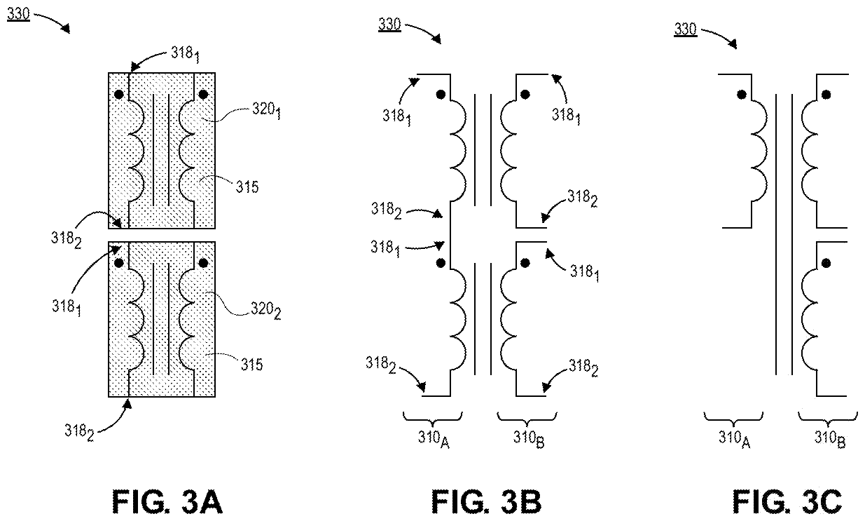

Referring now to FIG. 3A, a schematic of a modular transformer 330 is shown, in accordance with an embodiment. The modular transformer 330 includes a first transformer 320₁ and a second transformer 320₂. The first transformer 320₁ and the second transformer 320₂ may be embedded in separate magnetic layers 315. As shown, the modular transformer 330 is shown without electrical connections between the pads 318. For example, the first pads 318₁ and the second pads 318₂ are unconnected.

Referring now to FIG. 3B, an electrical equivalent circuit of the modular transformer 330 after connections are made is shown, in accordance with an embodiment. As shown, the primary winding 310_{A} includes inductors that are connected in series. That is, the second pad 318₂ of the top inductor is electrically connected to the first pad 318₁ of the bottom inductor. The first pad 318₁ on the top inductor may be connected to a first VR circuitry block (not shown), and the second pad 318₂ may be connected to the first VR circuitry block. On the side of the secondary windings 310_{B} the top inductor remains electrically isolated from the bottom inductor. As such, the secondary windings are able to provide separate voltage domains. On the side of the secondary windings 310_{B}, the top inductor may be connected to a second VR circuitry block (not shown), and the bottom inductor may be connected to a third VR circuitry block (not shown). In an embodiment, such a interconnect configuration allows for the formation of a 2:1 ratio transformer.

Referring now to FIG. 3C, an electrical equivalent circuit of the 2:1 ratio modular transformer 330 is shown, in accordance with an embodiment. As shown, the primary winding 310_{A} is electrically equivalent to a single inductor with an inductance equal to the inductance of the top inductor added to the inductance of the bottom inductor. Additionally, the secondary windings 310_{B} remain as discrete inductors.

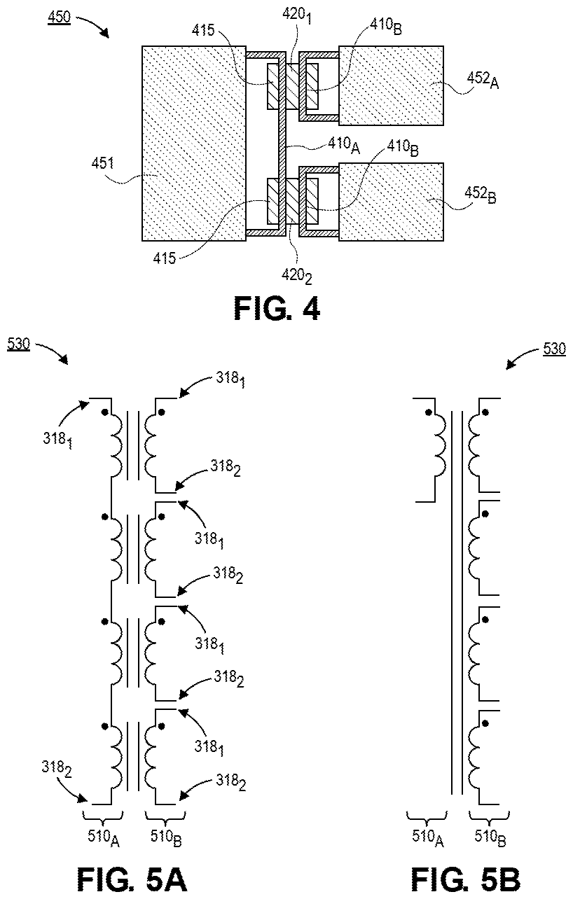

Referring now to FIG. 4, a schematic illustration of a VR module 450 is shown, in accordance with an embodiment. The VR module 450 includes a first transformer module 420₁ and a second transformer module 420₂. The first transformer module 420₁ and the second transformer module 420B may comprise a magnetic material 415 with conductive routing there through. On the primary side of the transformer modules 420₁ and 420₂ a single conductive core 410A passes through both transformer modules 420₁ and 420₂. A first end and a second end of the conductive core 410A may be electrically connected to a first VR circuitry block 451. On the secondary side of the transformer modules 420₁ and 420₂, each transformer module 420 may include an electrically distinct conductive core 410_{B}. In the first transformer module 420₁, the conductive core 410_{B} is connected to a second VR circuitry block 452A. In the second transformer module 420₂, the conductive core 410_{B} is connected to a third VR circuitry block 452_{B}. The second VR circuitry block 452A and the third VR circuitry block 452_{B} may be on different domains.

In FIGS. 3A-4, the modular transformer 330 is shown as having a pair of transformer modules 320/420. However, it is to be appreciated that any number of transformer modules 320/420 may be provided in the modular transformer to provide any desired ratio. For example, the first cores of each transformer module may be connected together in series, and the second cores of each transformer are electrically isolated from each other to provide a plurality of different domains. Additionally, while two conductive cores 310/410 are shown in each transformer module 320/420, it is to be appreciated that any number of conductive cores 310/410 may be embedded in a magnetic layers 315/415. For example, three or more conductive cores 310/410 may be embedded in a magnetic layer 315/415.

Referring now to FIGS. 5A and 5B, electrical equivalent circuit diagrams of a modular transformer 530 with a 4:1 ratio are shown, in accordance with an additional embodiment. As shown in FIG. 5A, on the side of the primary conductive core 510_{A}, the four inductors are connected in series between a first pad 318₁ of the topmost inductor and a second pad 318₂ of a bottommost inductor. On the side of the secondary conductive cores 510_{B}, each inductor is electrically isolated from other inductors. As such, a first pad 318₁ and a second pad 318₂ is free for each of the inductors. Each inductor on the secondary side of the conductive cores 510_{B} may be electrically coupled to different VR circuitry blocks (not shown) that are on different domains. As shown in FIG. 5B, the side of the primary conductive core 510_{A} is the electrical equivalent of a single inductor with an inductance equal to the sum of the individual inductors. As such, a 4:1 transformer ratio is provided.

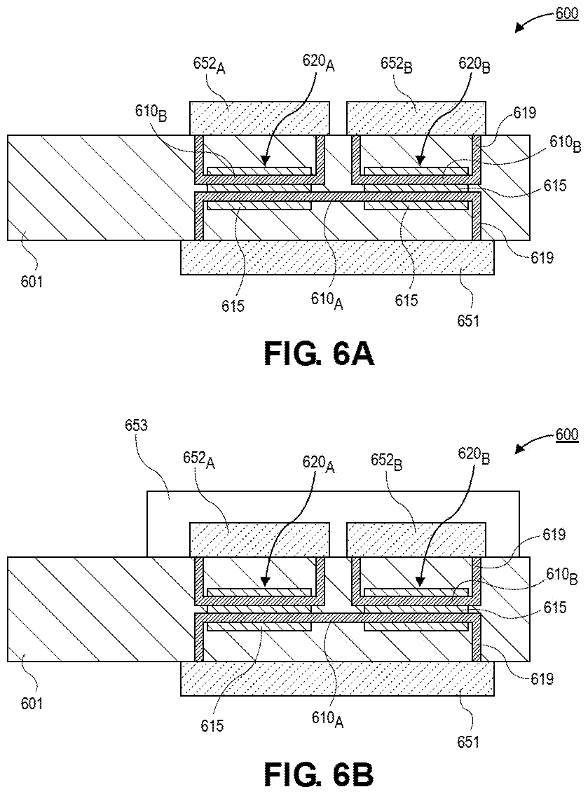

Referring now to FIGS. 6A and 6B, cross-sectional illustrations depicting the integration of a modular transformer into an electronic package 600 are shown, in accordance with an embodiment.

Referring now to FIG. 6A, a cross-sectional illustration of an electronic package 600 is shown, in accordance with an embodiment. In an embodiment, the electronic package comprises a package substrate 601. The package substrate 601 may include one or more insulative buildup layers with conductive routing (e.g., traces, pads, vias, etc.). The package substrate 601 may comprise a core, or the package substrate 601 may be coreless.

In an embodiment, a first VR circuit block 651 may be provided on a first surface of the package substrate 601, and second and third VR circuit blocks 652_{A} and 652_{B} may be provided on a second surface of the package substrate 601. The VR circuit blocks 651, 652_{A}, and 652_{B} may be integrated into one or more different dies, such as a system on a chip (SoC), or the like. In other embodiments, the VR circuit blocks 651, 652_{A}, and 652_{B} may be integrated as discrete dies.

In an embodiment, the modular transformer is embedded in the package substrate 601. For example, a first transformer module 620_{A} and a second transformer module 620_{B} may be embedded in one or more layers of the package substrate 601. The transformer modules 620_{A} and 620_{B} may be discrete components that are embedded in the package substrate 601. In other embodiments, the transformer modules 620_{A} and 620_{B} may be coupled together as a single discrete component that is embedded in the package substrate 601.

In an embodiment, the transformer modules 620_{A} and 620_{B} may each comprise a magnetic layer 615 that surrounds conductive cores 610. On a primary side of the transformer modules 620_{A} and 620_{B}, conductive cores 610_{A} are connected together in series, as described above. Ends of the combined conductive core 610_{A} are connected to the first VR circuitry block 651 by interconnects 619. The interconnects 619 may comprise conductive routing (e.g., pads, traces, vias, etc.) in the package substrate 601. On a secondary side of the transformer modules 620_{A} and 620_{B}, each transformer module 620_{A} and 620_{B} may comprise discrete second conductive cores 610_{B}. Each of the second conductive cores 610E may be electrically coupled to different VR circuitry blocks 652 (e.g., a second VR circuitry block 652_{A} or a third VR circuitry block 652_{B}) by interconnects 619. The interconnects 619 may comprise conductive routing (e.g., pads, traces, vias, etc.) in the package substrate 601.

Referring now to FIG. 6B, a cross-sectional illustration of an electronic package 600 is shown, in accordance with an additional embodiment. The electronic package 600 in FIG. 6B may be substantially similar to the electronic package 600 in FIG. 6A, with the exception that the second VR circuitry block 652_{A} and the third VR circuitry block 652_{B} are provided in a single die 653. In an embodiment, the single die 653 may be an SoC or any other type of die.

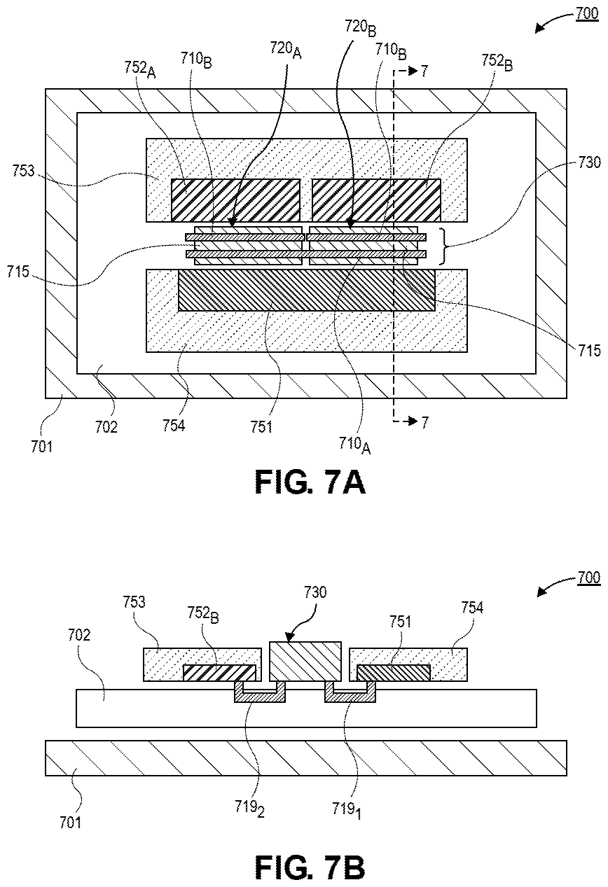

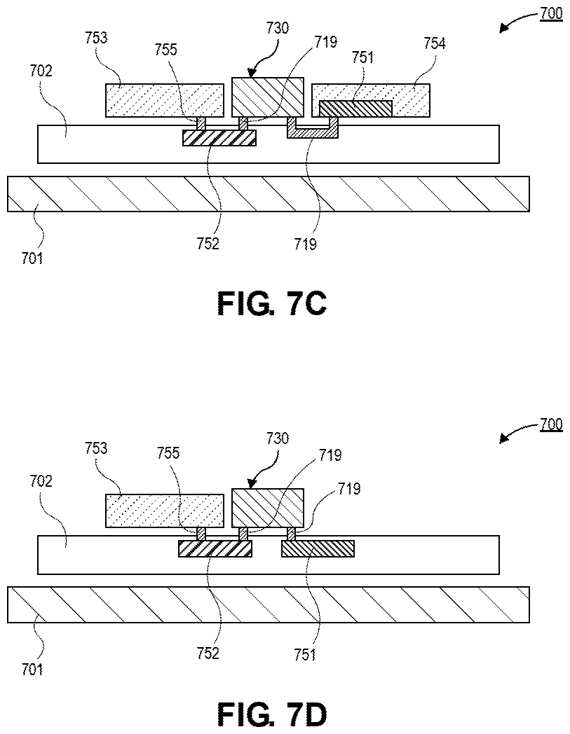

Referring now to FIG. 7A, a plan view illustration of an electronic package 700 is shown, in accordance with an embodiment. In an embodiment, the electronic package 700 comprises a package substrate 701 and an interposer 702 over the package substrate 701. The package substrate 701 may comprise insulative layers with conductive routing (not shown). The package substrate 701 may be cored or coreless. In an embodiment, the interposer 702 may comprise any suitable interposer substrate, such as a semiconductor, glass, or the like. In some embodiments, the interposer 702 is a passive interposer. In other embodiments, the interposer 702 includes active circuitry. In an embodiment, the package substrate 701 may be coupled to a board (not shown), such as a printed circuit board (PCB), a motherboard, or the like.

In an embodiment, a first die 754 is provided on the interposer 702, and a second die 753 is provided on the interposer 702. The first die 754 may comprise a first VR circuitry block 751, and the second die 753 may comprise a second VR circuitry block 752A and a third VR circuitry block 752_{B}. In an embodiment, a modular transformer 730 is provided as a discrete component between the first die 754 and the second die 753.

The modular transformer 730 may comprise a plurality of transformer modules 720. For example, a first transformer module 720A and a second transformer module 720B are shown in FIG. 7A. In an embodiment, the transformer modules 720A and 720B may comprise magnetic layers 715 that surround conductive cores 710. On the primary side of the modular transformer 730, conductive cores 710A are connected together in series, as described above. On the secondary side of the modular transformer 730, each transformer module 720 has an electrically isolated second core 710B.

Referring now to FIG. 7B, a cross-sectional illustration of the electronic package 700 in FIG. 7A along line 7-7 is shown, in accordance with an embodiment. In FIG. 7B, the modular transformer 730 is shown as a discrete component that is provided over the interposer 702. The modular transformer 730 may comprise a plurality of transformer modules, which are not shown in detail in order to simplify the illustration. Additionally, solder balls (or the like) between components (e.g., between the interposer 702 and the package substrate 701, between the dies 753/754 and the interposer 702, or between the modular transformer 730 and the interposer 702) are omitted for clarity.

In the illustrated embodiment, interconnects 719 between the modular transformer 730 and the VR circuitry blocks 752_{B} and 751 are shown. The interconnects may include conductive routing on/in the interposer 702. A first interconnect 719₁ provides an electrical coupling between the primary side of the modular transformer 730 and the first VR circuitry block 751, and a second interconnect 719₂ provides an electrical coupling between the secondary side of the modular transformer 730 and the second VR circuitry block 752_{B}.

Referring now to FIG. 7C, a cross-sectional illustration of an electronic package 700 is shown, in accordance with an additional embodiment. The electronic package 700 in FIG. 7C is substantially similar to the electronic package 700 in FIG. 7B, with the exception that the second VR circuitry block 752 is removed from the second die 753. Instead, the second VR circuitry block 752 is implemented in the interposer 702. In such an embodiment, the interposer 702 may be referred to as an active interposer 702 since switching circuitry is provided on the interposer 702. The second VR circuitry block 752 may be connected to the second die 753 by an interconnect 755. The interconnect 755 may comprise conductive routing, pads, a solder bump, or the like.

Referring now to FIG. 7D, a cross-sectional illustration of an electronic package 700 is shown, in accordance with another additional embodiment. The electronic package 700 in FIG. 7D may be substantially similar to the electronic package 700 in FIG. 7C, with the exception that the first VR circuitry block 751 is also implemented in the interposer 702.

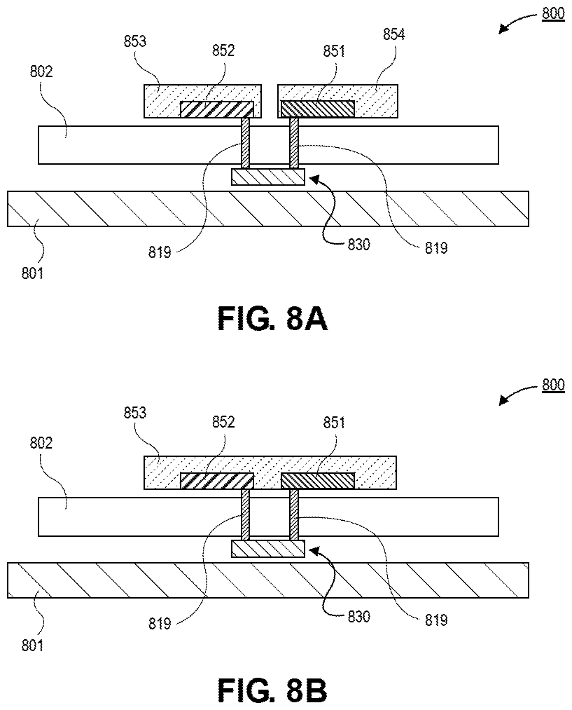

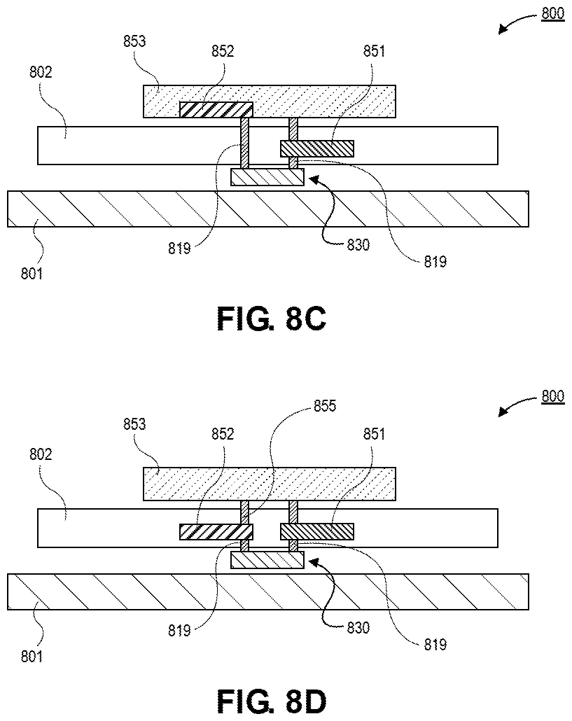

Referring now to FIGS. 8A-8D, cross-sectional illustrations of electronic packages 800 with the modular transformer 830 provided between the interposer 802 and the package substrate 801 is shown, in accordance with an embodiment. In FIGS. 8A-8D the modular transformer 830 is shown as a discrete block for simplicity. However, it is to be appreciated that the modular transformer 830 may comprise a plurality of transformer modules with the primary sides connected in series, and the secondary sides isolated to provide a plurality of different domains, similar to embodiments described in greater detail above. The space between the package substrate 801 and the interposer 802 may be provided by the standoff height of interconnects (not shown) between the package substrate 801 and the interposer 802. In an embodiment, the package substrate 801 may be coupled to a board (not shown), such as a PCB, a motherboard, or the like.

Referring now to FIG. 8A, a cross-sectional illustration of an electronic package 800 is shown, in accordance with an embodiment. In an embodiment, a primary side of the modular transformer 830 may be connected to a first VR circuitry block 851 in a first die 854 by an interconnect 819, and a secondary side of the modular transformer 830 may be connected to a second VR circuitry block 852 in a second die 853 by an interconnect 819. The first die 854 and the second die 853 may be provided on an opposite surface of the interposer 802 from the modular transformer 830. As such, the interconnects 819 may pass through the interposer 802 to provide the connections.

Referring now to FIG. 8B, a cross-sectional illustration of an electronic package 800 is shown, in accordance with an additional embodiment. In an embodiment, the electronic package 800 in FIG. 8B may be substantially similar to the electronic package 800 in FIG. 8A, with the exception of the first VR circuitry block 851 and the second VR circuitry block 852 being provided in the same first die 853.

Referring now to FIG. 8C, a cross-sectional illustration of an electronic package 800 is shown, in accordance with an additional embodiment. In an embodiment, the electronic package 800 in FIG. 8C is substantially similar to the electronic package 800 in FIG. 8B, with the exception that the first VR circuitry block 851 is implemented in the interposer 802 instead of the die 853. In such embodiments, the interposer 802 may be referred to as an active interposer since switching circuitry is provided on the interposer 802.

Referring now to FIG. 8D, a cross-sectional illustration of an electronic package 800 is shown, in accordance with an additional embodiment. In an embodiment, the electronic package 800 in FIG. 8D is substantially similar to the electronic package 800 in FIG. 8C, with the exception of the second VR circuitry block 852 also being implemented on the interposer 802. In an embodiment, the second VR circuitry block 852 may be electrically coupled to the die 853 by an interconnect 855.

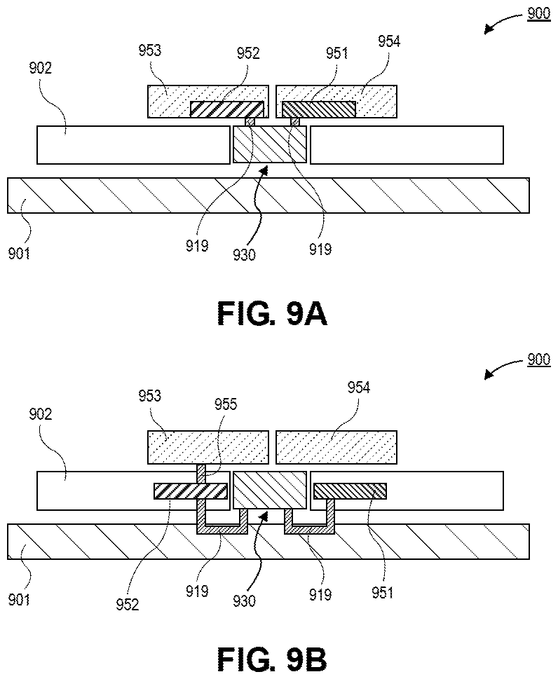

Referring now to FIGS. 9A and 9B cross-sectional illustrations of electronic packages 900 with an on-die interconnect (ODI) architecture are shown, in accordance with various embodiments. In FIGS. 9A and 9B the modular transformer 930 is shown as a discrete block for simplicity. However, it is to be appreciated that the modular transformer 930 may comprise a plurality of transformer modules with the primary sides connected in series, and the secondary sides isolated to provide a plurality of different domains, similar to embodiments described in greater detail above.

Referring now to FIG. 9A, a cross-sectional illustration of an electronic package 900 is shown, in accordance with an embodiment. In an embodiment, the electronic package 900 comprises a package substrate 901 and an interposer 902 over the package substrate 901. In an embodiment, the package substrate 901 may be coupled to a board (not shown), such as a PCB, a motherboard, or the like. In an embodiment, the modular transformer 930 may be provided over the package substrate 901 within a cavity through the interposer 902. The primary side of the modular transformer 930 may be connected by an interconnect 919 to a first VR circuitry block 951 in a first die 954 over the interposer 902, and the secondary side of the modular transformer 930 may be connected by an interconnect 919 to a second VR circuitry block 952 in a second die 953 over the interposer 902.

Referring now to FIG. 9B, a cross-sectional illustration of an electronic package 900 is shown, in accordance with an additional embodiment. The electronic package 900 in FIG. 9B may be substantially similar to the electronic package 900 in FIG. 9A, with the exception that the first VR circuitry block 951 and the second VR circuitry block 952 are implemented on the interposer 902. In order to provide the connections to the first VR circuitry block 951 and the second VR circuitry block 952, the interconnects 919 may pass over the package substrate 901. In an embodiment, the second VR circuitry block 952 may be electrically coupled to the second die 953 by an interconnect 955.

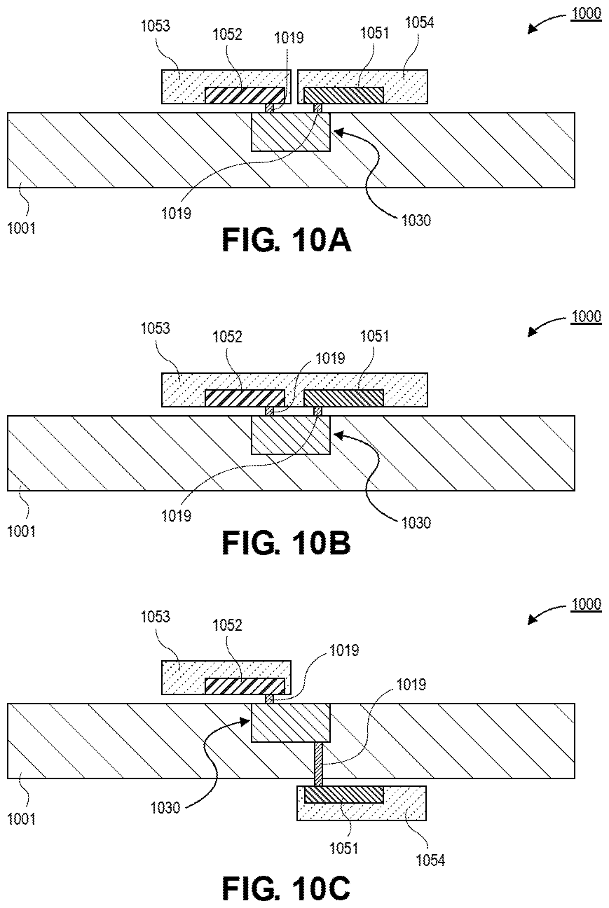

Referring now to FIGS. 10A-10C, a series of cross-sectional illustrations depicting electronic packages 1000 that include modular transformers 1030 that are integrated using an embedded bridge configuration are shown, in accordance with various embodiments. In FIGS. 10A-10C the modular transformer 1030 is shown as a discrete block for simplicity. However, it is to be appreciated that the modular transformer 1030 may comprise a plurality of transformer modules with the primary sides connected in series, and the secondary sides isolated to provide a plurality of different domains, similar to embodiments described in greater detail above.

Referring now to FIG. 10A, a cross-sectional illustration of an electronic package 1000 is shown, in accordance with an embodiment. In an embodiment, the electronic package 1000 comprises a package substrate 1001 with a first die 1054 and a second die 1053 over the package substrate 1001. The first die 1054 may comprise a first VR circuitry block 1051, and the second die 1053 may comprise a second VR circuitry block 1052. In an embodiment, the package substrate 1001 may be coupled to a board (not shown), such as a PCB, a motherboard, or the like.

In an embodiment, a modular transformer 1030 may be provided as a discrete component that is embedded in the package substrate 1001. A primary side of the modular transformer 1030 may be electrically coupled to the first VR circuitry block 1051 by an interconnect 1019, and a secondary side of the modular transformer 1030 may be electrically coupled to the second VR circuitry block 1052 by an interconnect 1019.

Referring now to FIG. 10B, a cross-sectional illustration of an electronic package 1000 is shown, in accordance with an additional embodiment. In an embodiment, the electronic package 1000 in FIG. 10B may be substantially similar to the electronic package 1000 in FIG. 10A, with the exception that the first VR circuitry block 1051 and the second VR circuitry block 1052 are implemented on a single die 1053.

Referring now to FIG. 10C, a cross-sectional illustration of an electronic package 1000 is shown, in accordance with an additional embodiment. In an embodiment, the electronic package 1000 in FIG. 10C may be substantially similar to the electronic package 1000 in FIG. 10A, with the exception that the first die 1054 is positioned on an opposite surface of the package substrate 1001. That is, the first die 1054 and the second die 1053 may be positioned on different surfaces of the package substrate 1001. In order to provide an electrical connection from the modular transformer 1030 to the first VR circuitry block 1051, the interconnect 1019 may pass through a thickness of the package substrate 1001.

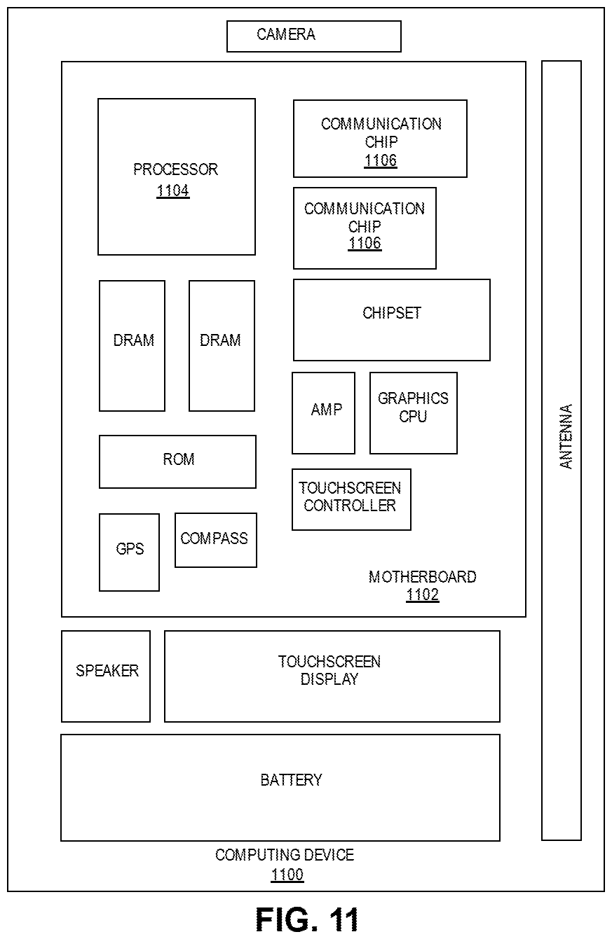

FIG. 11 illustrates a computing device 1100 in accordance with one implementation of the invention. The computing device 1100 houses a board 1102. The board 1102 may include a number of components, including but not limited to a processor 1104 and at least one communication chip 1106. The processor 1104 is physically and electrically coupled to the board 1102. In some implementations the at least one communication chip 1106 is also physically and electrically coupled to the board 1102. In further implementations, the communication chip 1106 is part of the processor 1104.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1106 enables wireless communications for the transfer of data to and from the computing device 1100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1106 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1100 may include a plurality of communication chips 1106. For instance, a first communication chip 1106 may be dedicated to shorter range wireless communications such as Wi-Fi and Bluetooth and a second communication chip 1106 may be dedicated to longer range wireless communications such as GPS, EDGE, GPRS, CDMA, WiMAX, LTE, Ev-DO, and others.

The processor 1104 of the computing device 1100 includes an integrated circuit die packaged within the processor 1104. In some implementations of the invention, the integrated circuit die of the processor may be coupled to an electronic package that comprises a modular transformer that comprises a plurality of transformer modules with the primary sides connected in series, and the secondary sides isolated to provide a plurality of different domains, in accordance with embodiments described herein. The term “processor” may refer to any device or portion of a device that processes electronic data from registers and/or memory to transform that electronic data into other electronic data that may be stored in registers and/or memory.

The communication chip 1106 also includes an integrated circuit die packaged within the communication chip 1106. In accordance with another implementation of the invention, the integrated circuit die of the communication chip may be coupled to an electronic package that comprises a modular transformer that comprises a plurality of transformer modules with the primary sides connected in series, and the secondary sides isolated to provide a plurality of different domains, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a transformer module, comprising: a first core, wherein the first core is conductive; a second core adjacent to the first core, wherein the second core is conductive; a magnetic layer around the first core and the second core; a first via through the magnetic layer and connected to the first core; a second via through the magnetic layer and connected to the first core; a third via through the magnetic layer and connected to the second core; and a fourth via through the magnetic layer and connected to the second core.

Example 2: the transformer module of Example 1, wherein the first via and the third via are proximate to a first end of the transformer module, and wherein the second via and the fourth via are proximate to a second end of the transformer module.

Example 3: the transformer module of Example 2, further comprising: a fifth via through the magnetic layer and connected to the first core, wherein the fifth via is between the first via and the second via; and a sixth via through the magnetic layer and connected to the second core, wherein the sixth via is between the third via and the fourth via.

Example 4: the transformer module of Examples 1-3, further comprising: an insulating layer between the magnetic layer and the first core and between the magnetic layer and the second core.

Example 5: the transformer module of Examples 1-4, further comprising: a third core embedded in the magnetic layer, wherein the third core is conductive.

Example 6: the transformer module of Examples 1-5, wherein the transformer module is embedded in a package substrate.

Example 7: the transformer module of Examples 1-6, wherein the first via and the second via are electrically coupled to a first voltage regulator (VR) circuit, and wherein the third via and the fourth via are electrically coupled to a second VR circuit.

Example 8: a transformer, comprising: a plurality of transformer modules, wherein individual ones of the plurality of transformer modules comprise: a first core, wherein the first core is conductive; a second core, wherein the second core is conductive; and a magnetic layer around the first core and the second core; and wherein the first cores of individual ones of the plurality of transformer modules are connected together in series, and wherein the second cores of individual ones of the plurality of transformer modules are electrically isolated from each other.

Example 9: the transformer of Example 8, wherein the plurality of transformer modules comprises two transformer modules, and wherein the transformer is a 2:1 transformer.

Example 10: the transformer of Example 8, wherein the plurality of transformer modules comprises four transformer modules, and wherein the transformer is a 4:1 transformer.

Example 11: the transformer of Examples 8-10, wherein individual ones of the second cores are electrically coupled to different voltage domains.

Example 12: the transformer of Examples 8-11, further comprising: insulating layers between the first core and the magnetic layer and the second core and the magnetic layer.

Example 13: the transformer of Examples 8-12, wherein individual ones of the transformer modules further comprise: a first via through the magnetic layer and connected to the first core; a second via through the magnetic layer and connected to the first core; a third via through the magnetic layer and connected to the second core; and a fourth via through the magnetic layer and connected to the second core.

Example 14: the transformer of Example 13, wherein the second via of a first transformer module is electrically coupled to the first via of a second transformer module in series.

Example 15: the transformer of Examples 8-14, wherein the transformer is embedded in a package substrate.

Example 16: the transformer of Examples 8-14, wherein the transformer is a discrete component electrically coupled to one or more chiplets in an electronic package.

Example 17: an electronic package, comprising: a package substrate; a first voltage regulator (VR) circuitry block; a second VR circuitry block; and a modular transformer electrically coupled to the first VR circuitry block and the second VR circuitry block, wherein the modular transformer comprises: a plurality of transformers, wherein individual ones of the plurality of transformers comprise: a first core, wherein the first core is conductive; a second core, wherein the second core is conductive; and a magnetic layer around the first core and the second core; and wherein the first cores of individual ones of the plurality of transformer modules are connected together in series, and wherein the second cores of individual ones of the plurality of transformer modules are electrically isolated from each other.

Example 18: the electronic package of Example 17, wherein the modular transformer is embedded in the package substrate.

Example 19: the electronic package of Example 18, wherein the first VR circuitry block and the second VR circuitry block are implemented on a single die.

Example 20: the electronic package of Example 18, wherein the first VR circuitry block and the second VR circuitry block are on opposite sides of the package substrate.

Example 21: the electronic package of Example 17, further comprising: an interposer over the package substrate.

Example 22: the electronic package of Example 21, wherein the modular transformer is over the interposer, embedded in the interposer, or below the interposer.

Example 23: the electronic package of Example 21 or Example 22, wherein one or both of the first VR circuitry block and the second VR circuitry block are implemented on the interposer.

Example 24: an electronic system, comprising: a board; a package substrate coupled to the board; a die coupled to the package substrate, wherein the die comprises voltage regulator (VR) circuitry; and a modular transformer electrically coupled to the VR circuitry.

Example 25: the electronic system of Example 24, wherein the modular transformer comprises: a plurality of transformer modules, wherein individual ones of the plurality of transformer modules comprise: a first core, wherein the first core is conductive; a second core, wherein the second core is conductive; and a magnetic layer around the first core and the second core; and wherein the first cores of individual ones of the plurality of transformer modules are connected together in series, and wherein the second cores of individual ones of the plurality of transformer modules are electrically isolated from each other.

What is claimed is:

1. A transformer module, comprising:
a first core, wherein the first core is conductive;
a second core adjacent to the first core, wherein the second core is conductive;
a magnetic layer around the first core and the second core;
a first via through the magnetic layer and connected to the first core;
a second via through the magnetic layer and connected to the first core;
a third via through the magnetic layer and connected to the second core; and
a fourth via through the magnetic layer and connected to the second core.

2. The transformer module of claim 1, wherein the first via and the third via are proximate to a first end of the transformer module, and wherein the second via and the fourth via are proximate to a second end of the transformer module.

3. The transformer module of claim 2, further comprising:
a fifth via through the magnetic layer and connected to the first core, wherein the fifth via is between the first via and the second via; and
a sixth via through the magnetic layer and connected to the second core, wherein the sixth via is between the third via and the fourth via.

4. The transformer module of claim 1, further comprising:
an insulating layer between the magnetic layer and the first core and between the magnetic layer and the second core.

5. The transformer module of claim 1, further comprising:
a third core embedded in the magnetic layer, wherein the third core is conductive.

6. The transformer module of claim 1, wherein the transformer module is embedded in a package substrate.

7. The transformer module of claim 1, wherein the first via and the second via are electrically coupled to a first voltage regulator (VR) circuit, and wherein the third via and the fourth via are electrically coupled to a second VR circuit.

8. A transformer, comprising:
a plurality of transformer modules, wherein individual ones of the plurality of transformer modules comprise:
a first core, wherein the first core is conductive;
a second core, wherein the second core is conductive; and
a magnetic layer around the first core and the second core; and
wherein the first cores of individual ones of the plurality of transformer modules are connected together in series, and wherein the second cores of individual ones of the plurality of transformer modules are electrically isolated from each other.

9. The transformer of claim 8, wherein the plurality of transformer modules comprises two transformer modules, and wherein the transformer is a 2:1 transformer.

10. The transformer of claim 8, wherein the plurality of transformer modules comprises four transformer modules, and wherein the transformer is a 4:1 transformer.

11. The transformer of claim 8, wherein individual ones of the second cores are electrically coupled to different voltage domains.

12. The transformer of claim 8, further comprising:
insulating layers between the first core and the magnetic layer and the second core and the magnetic layer.

13. The transformer of claim 8, wherein individual ones of the transformer modules further comprise:
a first via through the magnetic layer and connected to the first core;
a second via through the magnetic layer and connected to the first core;
a third via through the magnetic layer and connected to the second core; and
a fourth via through the magnetic layer and connected to the second core.

14. The transformer of claim 13, wherein the second via of a first transformer module is electrically coupled to the first via of a second transformer module in series.

15. The transformer of claim 8, wherein the transformer is embedded in a package substrate.

16. The transformer of claim 8, wherein the transformer is a discrete component electrically coupled to one or more chiplets in an electronic package.

17. An electronic package, comprising:
a package substrate;
a first voltage regulator (VR) circuitry block;
a second VR circuitry block; and
a modular transformer electrically coupled to the first VR circuitry block and the second VR circuitry block, wherein the modular transformer comprises:
a plurality of transformers, wherein individual ones of the plurality of transformers comprise:
a first core, wherein the first core is conductive;
a second core, wherein the second core is conductive; and
a magnetic layer around the first core and the second core; and
wherein the first cores of individual ones of the plurality of transformer modules are connected together in series, and wherein the second cores of individual ones of the plurality of transformer modules are electrically isolated from each other.

18. The electronic package of claim 17, wherein the modular transformer is embedded in the package substrate.

19. The electronic package of claim 18, wherein the first VR circuitry block and the second VR circuitry block are implemented on a single die.

20. The electronic package of claim 18, wherein the first VR circuitry block and the second VR circuitry block are on opposite sides of the package substrate.

21. The electronic package of claim 17, further comprising:
an interposer over the package substrate.

22. The electronic package of claim 21, wherein the modular transformer is over the interposer, embedded in the interposer, or below the interposer.

23. The electronic package of claim 21, wherein one or both of the first VR circuitry block and the second VR circuitry block are implemented on the interposer.

24. An electronic system, comprising:
a board;
a package substrate coupled to the board;
a die coupled to the package substrate, wherein the die comprises voltage regulator (VR) circuitry; and
a modular transformer electrically coupled to the VR circuitry.

25. The electronic system of claim 24, wherein the modular transformer comprises:
a plurality of transformer modules, wherein individual ones of the plurality of transformer modules comprise:
a first core, wherein the first core is conductive;
a second core, wherein the second core is conductive; and
a magnetic layer around the first core and the second core; and
wherein the first cores of individual ones of the plurality of transformer modules are connected together in series, and wherein the second cores of individual ones of the plurality of transformer modules are electrically isolated from each other.
